(19) United States
(12) Patent Application Publication
(10) Pub. No.: US 2025/0006276 A1
(43) Pub. Date: Jan. 2, 2025

(54) NON-VOLATILE MEMORY DEVICE

(71) Applicant: ROHM CO., LTD., Kyoto-shi (JP)

(72) Inventor: Seiji TAKENAKA, Kyoto-shi (JP)

(21) Appl. No.: 18/886,194

(22) Filed: Sep. 16, 2024

Related U.S. Application Data
(63) Continuation of application No. PCT/JP2023/008037, filed on Mar. 3, 2023.

(30) Foreign Application Priority Data
Mar. 17, 2022 (JP) 2022-042611

(51) Int. Cl. G11C 16/30

(52) U.S. Cl. CPC G11C 16/30

(57) ABSTRACT

A non-volatile memory device includes: a first current mirror having a reference element configured as a memory element for which a program operation can be performed, and a data element configured as the memory element and targeted by the program operation; a reference current generator connected to the data element and configured to generate a reference current; and a storage circuit having the data element and the reference current generator. The storage circuit can read data based on the magnitude relationship between the current flowing through the data element and the reference current.

### CROSS-REFERENCE TO RELATED APPLICATIONS

This application is a continuation under 35 U.S.C. § 120 of PCT/JP2023/008037 filed on Mar. 3, 2023, which is incorporated herein by reference, and which claims priority to Japanese Application No. 2022-042611 filed on Mar. 17, 2022. The present application likewise claims priority under 35 U.S.C. § 119 to Japanese Application No. 2022-042611 filed on Mar. 17, 2022, the entire contents of which is also incorporated herein by reference.

### TECHNICAL FIELD

The present disclosure relates to a non-volatile memory device.

### BACKGROUND ART

Some known non-volatile memory devices employ hot carrier injection into transistors. This kind of non-volatile memory device includes as memory elements a first and a second transistor that have paired characteristics in their initial state and the characteristics of one of the transistors are changed by hot carrier injection. After that, in a read operation, based on the magnitude relationship between the drain currents of the first and second transistors as observed when a common gate voltage is fed to them, whether data “0” or data “1” is stored is read out. For example, a state where the drain current of the first transistor is lower (a state where the characteristics of the first transistor have been changed) corresponds to a state where data “0” is stored, and a state where the drain current of the second transistor is lower (a state where the characteristics of the second transistor have been changed) corresponds to a state where data “1” is stored.

An example of technology related to what has just been mentioned is disclosed in Patent Document 1.

### CITATION LIST

### Patent Literature

Patent Document 1: Japanese Unexamined Patent Application Publication No. 2011-103158

### BRIEF DESCRIPTION OF DRAWINGS

FIG. 1 is a diagram showing the configuration of a non-volatile memory device according to a comparative example.

FIG. 2 is a diagram showing the gate-source voltage dependence of the drain current of a data element.

FIG. 3 is a timing chart showing an example of the waveforms of a signal XRST, a voltage V1 on a line Ln1, and a voltage V2 on a line Ln2.

FIG. 4 is a diagram showing the configuration of a non-volatile memory device according to an embodiment of the present disclosure.

### DESCRIPTION OF EMBODIMENTS

Hereinafter, an illustrative embodiment will be described with reference to the drawings. Any of the non-volatile memory devices described below can be configured as a semiconductor integrated circuit.

### 1. Comparative Example

Before a description of an embodiment of the present disclosure, a comparative example will be described. The description of the comparative example will clarify the significance of the embodiment of the present disclosure.

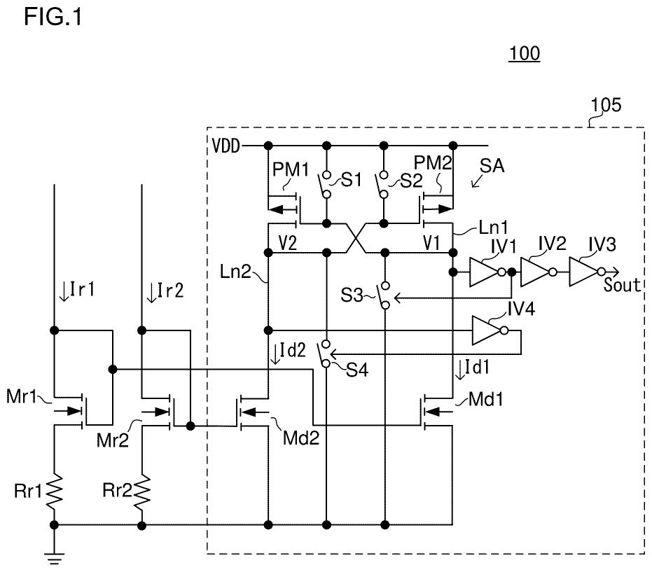

FIG. 1 is a diagram showing the configuration of a non-volatile memory device 100 according to the comparative example. The non-volatile memory device 100 includes a storage circuit 105, a first reference element Mr1, a second reference element Mr2, a first reference resistor Rr1, and a second reference resistor Rr2.

The storage circuit 105 is a circuit for storing one-bit data and has a first data element Md1, a second data element Md2, and a sense amplifier SA.

According to the combination of the first and second data elements Md1 and Md2, data “0” or data “1” is stored.

The data elements Md1 and Md2 and the reference elements Mr1 and Mr2 are both configured as memory elements and are configured, more specifically, as NMOS transistors (N-channel MOSFET (metal-oxide-semiconductor field-effect transistors)). A memory element is an element for which a program operation can be performed by changing the characteristics of a transistor by hot carrier injection and is also called an OTP (one-time programmable) element.

The gate and the drain of the first reference element Mr1 are short-circuited together. The source of the first reference element Mr1 is connected to one terminal of the first reference resistor Rr1. The other terminal of the first reference resistor Rr1 is connected to a ground terminal (an application terminal for a ground potential).

The gate of the first data element Md1 is connected to the gate of the first reference element Mr1. The source of the first data element Md1 is connected to the ground terminal. The drain of the first data element Md1 is connected to one input terminal of the sense amplifier SA.

The gate and the drain of the second reference element Mr2 are short-circuited together. The source of the second reference element Mr2 is connected to one terminal of the second reference resistor Rr2. The other terminal of the second reference resistor Rr2 is connected to the ground terminal.

The gate of the second data element Md2 is connected to the gate of the second reference element Mr2. The source of the second data element Md2 is connected to the ground terminal. The drain of the second data element Md2 is connected to the other input terminal of the sense amplifier SA.

Thus, the first reference element Mr1 and the first data element Md1, and the second reference element Mr2 and the second data element Md2, each constitute a current mirror.

The first and second reference resistors Rr1 and Rr2 have the same resistance value. The data elements Md1 and Md2 and the reference elements Mr1 and Mr2 have the same structure and have the same electrical characteristics before the program operation is performed. The target of the program operation is the data elements Md1 and Md2. Thus, before the program operation is performed, the data elements Md1 and Md2 and the reference elements Mr1 and Mr2 have the same gate threshold value voltage. The Vgs (gate-source voltage) of the data element Md1 is a voltage that is the sum of the Vgs of the reference element Mr1 and the voltage across the first reference resistor Rr1. The Vgs of the data element Md2 is a voltage that is the sum of the Vgs of the reference element Mr2 and the voltage across the second reference resistor Rr2.

Thus, before the program operation is performed in the data elements Md1 and Md2, the drain currents Id1 and Id2 through the data elements Md1 and Md2 and the drain currents Ir1 and Ir2 through the reference elements Mr1 and Mr2 have a magnitude relationship such that Id1>Ir1 and Id2>Ir2. Moreover, Ir1=Ir2, and thus Id1=Id2. Accordingly, there is no difference between the currents through the data elements Md1 and Md2, and thus the data is left indefinite. That is, in the non-volatile memory device 100 of this configuration, no initial value is set for the data in the data elements Md1 and Md2 in a state where the program operation has not yet been performed.

Here, with respect to a transistor, “structure” is a concept that covers the size of the transistor, and thus, with respect to a given plurality of transistors, their having the same structure means that the sizes of those transistors are also the same. When a plurality of transistors have the same structure, if they have not yet been subjected to hot carrier injection by the program operation, those transistors have the same electrical characteristics (including the gate threshold values and the like). Note however that a given plurality of transistors having the same structure, and the same electrical characteristics means that those are the same in design and allow for errors in reality (i.e., “same” is a concept that allows for errors).

In the non-volatile memory device 100, a read operation to read out the data stored in the data elements Md1 and Md2 and a program operation (write operation) to rewrite the data (logical value) stored in the data elements Md1 and Md2 can be performed.

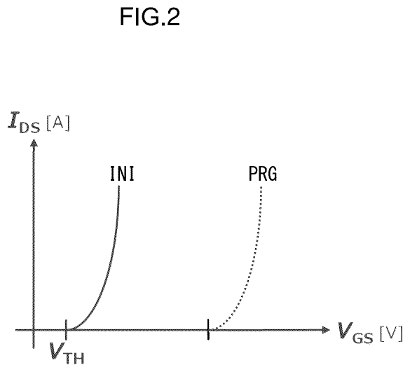

The program operation is carried out by a program circuit (not illustrated). In the program operation, the program circuit changes the electrical characteristics of the data elements Md1 and Md2 by injecting hot carriers into the data elements Md1 and Md2. This change raises the gate threshold value voltage of the data elements Md1 and Md2. In FIG. 2, a solid-line waveform INI indicates the gate-source voltage dependence of the drain current of the data elements Md1 and Md2 before the program operation is performed and a dotted-line waveform PRG indicates the gate-source voltage dependence of the drain current of the data elements Md1 and Md2 after the program operation is performed. In this way, the program operation raises the gate threshold value voltage Vth.

The program operation is performed, for example, by feeding the gates of the data elements Md1 and Md2 with a supply voltage VDD, their sources with VDD, and their drains with the ground potential (0 V).

In a state where the drain currents Ir1 and Ir2 are fed, in a read operation, the sense amplifier SA, based on the magnitude relationship between the drain currents Id1 and Id2 of the data elements Md1 and Md2, outputs an output signal Sout that corresponds to the stored data value (logical value).

Performing the program operation so as to inject hot carriers into, of the data elements Md1 and Md2 before the program operation is performed, the first data element Md1 results in raising the gate threshold value voltage of the first data element Md1. Thus, after the program operation is performed, the gate threshold value voltage of the first data element Md1 is higher than the gate threshold value voltage of the second data element Md2. Accordingly, the drain currents Id1 and Id2 have a magnitude relationship such that Id1<Id2. A state in which the drain current Id1 is lower than the drain current Id2 corresponds to a state in which data “0” is stored. Thus, in the read operation, if the drain current Id1 is lower than the drain current Id2, the sense amplifier SA outputs an output signal Sout (low-level Sout) that corresponds to data “0”.

By contrast, performing the program operation so as to inject hot carriers into, of the data elements Md1 and Md2 before the program operation is performed, the second data element Md2 results in raising the gate threshold value voltage of the second data element Md2. Thus, after the program operation is performed, the gate threshold value voltage of the second data element Md2 is higher than the gate threshold value voltage of the first data element Md1. Accordingly, the drain currents Id1 and Id2 have a magnitude relationship such that Id1>Id2. A state in which the drain current Id1 is higher than the drain current Id2 corresponds to a state in which data “1” is stored. Thus, in the read operation, if the drain current Id1 is higher than the drain current Id2, the sense amplifier SA outputs an output signal Sout (high-level Sout) that corresponds to data “1”.

As shown in FIG. 1, the sense amplifier SA includes PMOS transistors (P-channel MOSFET) PM1 and PM2, switches S1 and S2, switches S3 and S4, and inverters IV1 to IV4.

The source of the PMOS transistor PM2 is connected to an application terminal for the supply voltage VDD. The drain of the PMOS transistor PM2 is connected to a line Ln1. The gate of the PMOS transistor PM2 is connected to a line Ln2. The line Ln1 is connected to the drain of the first data element Md1. The line Ln2 is connected to the drain of the second data element Md2.

The source of the PMOS transistor PM1 is connected to the application terminal for the supply voltage VDD. The drain of the PMOS transistor PM1 is connected to the line Ln2. The gate of the PMOS transistor PM1 is connected to the line Ln1.

Between the application terminal for the supply voltage VDD and the line Ln1, the switch S1 is connected. Between the application terminal for the supply voltage VDD and the line Ln2, the switch S2 is connected.

The input terminal of the inverter IV1 is connected to the line Ln1. The output terminal of the inverter IV1 is connected to the input terminal of the inverter IV2. The output terminal of the inverter IV2 is connected to the input terminal of the inverter IV3. The inverter IV3 outputs the output signal Sout.

Between the line Ln1 and the ground terminal, the switch S3 is connected. According to the output of the inverter IV1, the switch S3 is turned on and off. Between the line Ln2 and the ground terminal, the switch S4 is connected. The input terminal of the inverter IV4 is connected to the line Ln2. According to the output of the inverter IV4, the switch S4 is turned on and off.

A control circuit (not illustrated) can output a signal XRST and turn the switches S1 and S2 on and off.

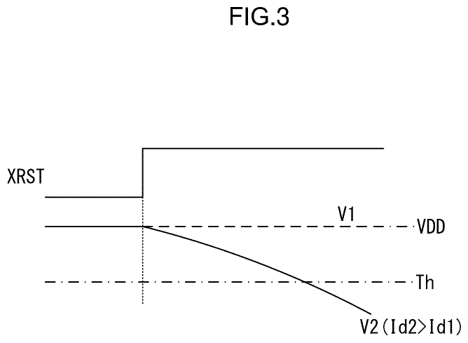

FIG. 3 is a timing chart showing an example of the waveforms of the signal XRST, the voltage V1 on the line Ln1, and the voltage V2 on the line Ln2. The operation of the sense amplifier SA will be described with reference also to FIG. 3. In the read operation, a period during which the signal XRST is at low level is called a pre-charge period and a period during which it is at high level is called a read period.

During the pre-charge period, in which the signal XRST is at low level, the drain currents Ir1 and Ir2 are off and the switches S1 and S2 are on. Thus, the gates and the sources of the PMOS transistors PM1 and PM2 are short-circuited together and the PMOS transistors PM1 and PM2 are off. A positive electric charge is fed to the line Ln1 via the switch S1, which is on, and the voltage V1 reaches the level of the supply voltage VDD. A positive electric charge is fed to the line Ln2 via the switch S2, which is on, and the voltage V2 too reaches the level of the supply voltage VDD. Meanwhile, the outputs of the inverters IV1 and IV4 are at low level, so the switches S3 and S4 are off.

Then, when the signal XRST is switched from low level to high level and a transition from the pre-charge period to the read period takes place, the drain currents Ir1 and Ir2 are on and the switches S1 and S2 are off. If the drain current Id2 flows, the voltage V2 falls and, if the drain current Id1 flows, the voltage V1 falls.

In the read operation after the program operation is performed for the first data element Md1, Id1=0 and Id2>Id1, so the voltage V2 falls (see V2 in FIG. 3 (Id2>Id1)). When the voltage V2 reaches a threshold value Th, the output of the inverter IV4 switches from low level to high level and the switch S4 is switched on. Thus, the voltage V2=0 V, the PMOS transistor PM2 is on, and the voltage V1=VDD. Meanwhile, the PMOS transistor PM1 is off. Accordingly, the output signal Sout output from the inverter IV3 is at low level. That is, the output signal Sout is output as a signal indicating a state where “0” is stored.

By contrast, in the read operation after the program operation is performed for the second data element Md2, Id2=0 and Id2<Id1, so the voltage V1 falls. When the voltage V1 reaches a threshold value Th, the output of the inverter IV1 switches from low level to high level and the switch S3 is switched on. Thus, the voltage V1=0 V, the PMOS transistor PM1 is on, and the voltage V2=VDD. Meanwhile, the PMOS transistor PM2 is off. Accordingly, the output signal Sout output from the inverter IV3 is at high level. That is, the output signal Sout is output as a signal indicating a state where “1” is stored.

As described above, in the non-volatile memory device 100 according to the comparative example, although there is no initial data value, data can be stored by performing the program operation for one of the data elements Md1 and Md2. One drawback here is a relatively large size of the storage circuit 105 for storing one-bit data. To adapt the non-volatile memory device 100 for data of a plurality of bits (for example, 32 bits), the storage circuit 105 needs to be provided one for each of the plurality of bits, and so size reduction is desired in the storage circuit 105.

### 2. Embodiment of Present Disclosure

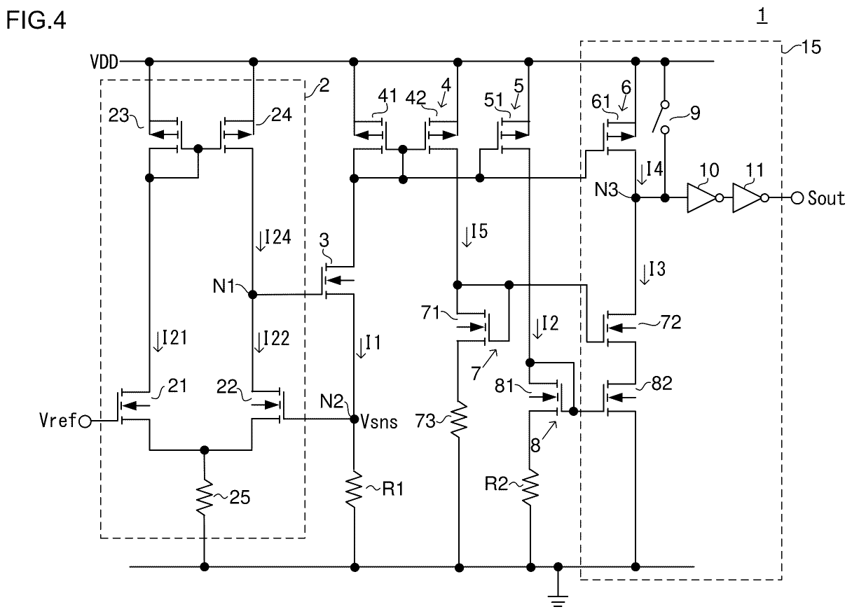

To solve the problem described above, the embodiment of the present disclosure is implemented. Hereinafter, the embodiment of the present disclosure will be described. FIG. 4 is a diagram showing the configuration of a non-volatile memory device 1 according to the embodiment of the present disclosure.

The non-volatile memory device 1 includes a differential amplifier 2, a driving transistor 3, current mirrors 4 to 8, a switch 9, and inverters 10 and 11.

The differential amplifier 2 has input transistors 21 and 22, PMOS transistors 23 and 24, and a resistive element 25. The input transistors 21 and 22 are both configured as NMOS transistors. The gate of the input transistor 21 is fed with a reference voltage Vref. The source of the input transistor 21 is connected to one terminal of the resistive element 25. The drain of the input transistor 21 is connected to the drain of the PMOS transistor 23. The gate and the drain of the PMOS transistor 23 are short-circuited together. The source of the PMOS transistor 23 is connected to an application terminal for a supply voltage VDD. The gate of the PMOS transistor 24 is connected to the gate of the PMOS transistor 23. The source of the PMOS transistor 24 is connected to the application terminal for the supply voltage VDD. The drain of the PMOS transistor 24 is connected to the drain of the input transistor 22. The source of the input transistor 22 is connected to one terminal of the resistive element 25. The other terminal of the resistive element 25 is connected to a ground terminal.

The driving transistor 3 is configured as an NMOS transistor. A node N1 at which the PMOS transistor 24 and the input transistor 22 are connected together is connected to the gate of the driving transistor 3. The source of the driving transistor 3 is connected to one terminal of a resistive element R1. The other terminal of the resistive element R1 is connected to the ground terminal. A node N2 at which the driving transistor 3 and the resistive element RI are connected together is connected to the gate of the input transistor 22.

In the differential amplifier 2, a current I21 according to a reference voltage Vref flows through the input transistor 21. The current I21 is mirrored by a current mirror constituted by the PMOS transistors 23 and 24 to produce a current I24 flowing through the PMOS transistor 24. A current I22 according to a sense voltage Vsns appearing at the node N2 flows through the input transistor 22. The gate of the driving transistor 3 is driven according to the balance between the currents I24 and I22 and thereby the on resistance of the driving transistor 3 is adjusted. That is, the differential amplifier 2 drives the gate of the driving transistor 3 according to the difference between the reference voltage Vref and the sense voltage Vsns. Thus, the sense voltage Vsns is controlled to remain equal to the reference voltage Vref. The differential amplifier 2, the driving transistor 3, and the resistive element R1 constitute a constant voltage circuit that keeps the sense voltage Vsns constant.

The current mirror 4 has an input-side transistor 41 and an output-side transistor 42, both of which are configured as PMOS transistors. The current mirror 5 has the input-side transistor 41 and an output-side transistor 51, both of which are configured as PMOS transistors. The current mirror 6 has the input-side transistor 41 and an output-side transistor 61, both of which are configured as PMOS transistors. That is, the current mirrors 4, 5, and 6 share the input-side transistor 41.

The current mirror 8 has a reference element 81, a data element 82, and a resistive element R2. The reference element 81 and the data element 82 are both memory elements (OTP elements) that are configured as NMOS transistors. As previously described, a memory element is an element that can perform a program operation. The data element 82 is the target of the program operation.

The gate and the drain of the reference element 81 is short-circuited together. The source of the reference element 81 is connected to one terminal of the resistive element R2. The other terminal of the resistive element R2 is connected to the ground terminal. The gate of the data element 82 is connected to the gate of the reference element 81. The source of the data element 82 is connected to the ground terminal.

The drain of the driving transistor 3 is connected to the input-side transistor 41 of the current mirror 5 (the current mirrors 4 and 6). The output-side transistor 51 of the current mirror 5 is connected to the drain of the reference element 81.

The drain of the data element 82 is connected to the output-side transistor 61 of the current mirror 6 at a node N3 via an output-side transistor 72 of a current mirror 7, which will be described later.

A current I1 generated by the sense voltage Vsns and the resistive element R1 is mirrored by the current mirror 5 to produce a current I2. The current I2 flows through the reference element 81 and the resistive element R2. The Vgs of the data element 82 is a voltage that is the sum of the Vgs of the reference element 81 and the voltage across the resistive element R2. The resistive element R2 is one example of a voltage adder that adds up voltages. The voltage adder is not limited to a resistive element and can be configured with, for example, a MOS transistor.

The reference element 81 and the data element 82 have the same structure and have the same electrical characteristics before the program operation is performed. Thus, in a state before the program operation is performed for the data element 82 (a state where the reference element 81 and the data element 82 are both unprogrammed), a current I3 flows through the data element 82 such that I3>I2.

On the other hand, the current I1 is mirrored by the current mirror 6 to produce a current I4. The current I4 that flows through the output-side transistor 61 of the current mirror 6 serves as a reference current. That is, the output-side transistor 61 is one example of a reference current generator. For example, if I1=I2=I4=1 μA, in a state before the program operation is performed for the data element 82, I3=3 μA.

The node N3 is connected to the input terminal of the inverter 10. The input terminal of the inverter 11 is connected to the output terminal of the inverter 10. An output signal Sout is output from the output terminal of the inverter I1.

The switch 9 is connected between the application terminal for the supply voltage VDD and the node N3. In the reset state with the switch 9 on, the voltage at the input terminal of the inverter 10 is fixed at high level and the output signal Sout is fixed at high level. If the switch 9 is turned off from the reset state, in a state before the program operation is performed for the data element 82, I3>I4 and a current is drawn to the node N3, so the voltage at the input terminal of the inverter 10 falls down to low level. With the current value in the above example, I3=3 μA and I4=1 μA, so a current of 2 μA is drawn to the node N3. Thus, the output signal Sout output from the inverter 11 is at low level. That is, the output signal Sout is output as a signal indicating a state where “0” is stored.

By contrast, in a state after the program operation is performed for the data element 82, the gate threshold voltage of the data element 82 is higher and I3=0. When the switch 9 is turned off from the reset state, in a state after the program operation is performed for the data element 82, I4>I3 and the voltage at the input terminal of the inverter 10 is kept at high level. Thus, the output signal Sout output from the inverter 11 is at high level. That is, the output signal Sout is output as a signal indicating a state where “1” is stored.

Thus, in this embodiment, in a state before the program operation is performed for the data element 82, the current mirror 8 generates a current I3 larger than the current I4 that is the reference current, and in a state after the program operation is performed for the data element 82, I3<I4. Then the magnitude relationship between the currents I3 and I4 is sensed by the inverters 10 and 11 and thereby one-bit data is read.

The non-volatile memory device 1 has a storage circuit 15. The storage circuit 15 has the data element 82, the output-side transistor 72, the output-side transistor 61, the switch 9, and the inverters 10 and 11. Thus, in the present embodiment, it is possible to reduce the storage circuit 15 in size corresponding to one-bit data. In practice, the non-volatile memory device 1 can handle a plurality of bits (for example, 32 bits) and the storage circuit 15 is provided one for each of the plurality of bits. The components in the configuration shown in FIG. 4 other than the storage circuit 15 are circuits shared by the plurality of bits (common circuits).

In this embodiment, the constant voltage circuit that keeps the sense voltage Vsns constant, the current mirror 5, and the resistive elements R1 and R2 accurately set the voltage added to the Vgs of the reference element 81. For example, setting the resistance value of R2 to one-half of R1 permits the added voltage mentioned above to set to one-half of Vsns.

If the switch 9 is connected between the node N3 and the ground terminal, when the switch 9 is turned off from the reset state, in a state after the program operation is performed for the data element 82, the current I4, which is the reference current (for example, 1 μA), causes the voltage at the input terminal of the inverter 10 to rise from low level to high level. In contrast, in this embodiment, the switch 9 is connected between the application terminal for the supply voltage VDD and the node N3, and thus, when the switch 9 is turned off from the reset state, in a state before the program operation is performed for the data element 82, the current drawn to the node N3 (I3-I4, for example, 2 μA) causes the voltage at the input terminal of the inverter 10 to fall from high level to low level. Thus, the current drawn to the node N3 is higher than I4, and this helps reduce the read time.

Though different from the configuration shown in FIG. 4, in the current mirror 8, the size of the data element 82 may be larger than the size of the reference element 81 (size of data element 82: size of reference element 81=1: M (M>1)). This eliminates the need for the resistive element R2. Also with this configuration, in a state before the program operation is performed for the data element 82, it is possible to pass a current I3 larger than the current I2 such that I3>I4.

Though different from the configuration shown in FIG. 4, in the output-side transistors 51 and 61, the size of the output-side transistor 51 may be larger than the size of the output-side transistor 61. This too eliminates the need for the resistive element R2. Also with this configuration, in a state before the program operation is performed for the data element 82, it is possible to achieve I3>I4.

Next, the current mirror 7 will be described. The current mirror 7 is cascode-connected to the current mirror 8. The current mirror 7 has an input-side transistor 71, the output-side transistor 72, and a resistive element 73.

The input-side transistor 71 and the output-side transistor 72 are both configured as NMOS transistors. The gate and the drain of the input-side transistor 71 are short-circuited together. The drain of the input-side transistor 71 is connected to the output-side transistor 42 of the current mirror 4. The source of the input-side transistor 71 is connected to one terminal of the resistive element 73. The other terminal of the resistive element 73 is connected to the ground terminal. The gate of the output-side transistor 72 is connected to the gate of the input-side transistor 71. The source of the output-side transistor 72 is connected to the drain of the data element 82. The drain of the output-side transistor 72 is connected to the node N3.

The current I1 is mirrored by the current mirror 4 to produce a current I5. The current I5 flows through the input-side transistor 71 and the resistive element 73. A voltage lower by the Vgs of the output-side transistor 72 than the voltage obtained by adding the voltage across the resistive element 73 to the Vgs of the input-side transistor 71 is applied as the drain voltage of the data element 82.

Thus, by fixing the drain voltage of the data element 82 at a voltage in the saturation region of its Vds-Ids characteristics, it is possible to stabilize the current I3. It is also possible to prevent a rise in the drain voltage of the data element 82 for which the program operation is performed by hot carrier injection and thereby to prevent the program operation from being erroneously performed on the data element 82.

### 3. Others

The various technical features disclosed herein can be implemented in any manners other than as in the above-described embodiments with any modifications made without departure from the spirit of their technical ingenuity. That is, it should be understood that the above-described embodiments are in every aspect illustrative and not restrictive. The technical scope of the present disclosure is defined not by the description of the embodiments given above but by the appended claims, and encompasses any modifications made within a scope equivalent in significance to those claims.

For example, the reference element 81 and the data element 82 are not limited to NMOS transistors and can be configured as PMOS transistors. If configured as PMOS transistors, the interconnections among the elements other than the reference element 81 and the data element 82 are changed as appropriate.

For example, the reference element 81 and the data element 82 are not limited to ones employing hot carrier injection, and can be configured as, for example, memory elements for which a program operation is performed by injecting electrons into a floating gate.

### 4. Notes

As described above, for example, according to one aspect of the present disclosure, a non-volatile memory device (1) includes:
a first current mirror (8) having:
   a reference element (81) configured as a memory element for which a program operation can be performed, and
   a data element (82) configured as the memory element, the data element being a target of the program operation;
a reference current generator (61) connected to the data element and configured to be operable to generate a reference current (I4); and
a storage circuit (15) having the data element and the reference current generator,
wherein
the storage circuit is operable to read data based on a magnitude relationship between a current (I3) flowing through the data element and the reference current. (A first configuration.)

The non-volatile memory device of the first configuration described above may further include a second current mirror (6) having a first input-side transistor (41) and a first output-side transistor (61). The reference current generator may be the first output-side transistor. (A second configuration.)

In the first or second configurations described above, the first current mirror (8) may have a voltage adder (R2) that adds a voltage to the gate-source voltage of the reference element (81). (A third configuration.)

In the third configuration described above, the voltage adder may be a first resistor (R2) connected to the source of the reference element (81). (A fourth configuration.)

Any one of the first to fourth configurations described above may further include:
a driving transistor (3);
a second resistor (R1) connected to the driving transistor;
a differential amplifier (2) that drives the driving transistor based on the difference between the reference voltage (Vref) and a sense voltage (Vsns) appearing at a first node (N2) at which the driving transistor and the second resistor are connected together; and
   a third current mirror (5) having a second input-side transistor (41) connected to the driving transistor and a second output-side transistor (51) connected to the reference element (81). (A fifth configuration.)

In the first or second configurations described above, the size of the data element (82) may be larger than the size of the reference element (81). (A sixth configuration.)

In any one of the first to sixth configurations described above, the storage circuit (15) may have a switch (9) connected between an application terminal for a supply voltage (VDD) and a second node (N3) at which the reference current generator (61) and the data element (82) are connected together. (A seventh configuration.)

Any one of the first to seventh configurations described above may further include a fourth current mirror (7) having a third input-side transistor (71), a third output-side transistor (72) connected to the drain of the data element (82), and a third resistor (73) connected to the third input-side transistor. (An eighth configuration.)

### INDUSTRIAL APPLICABILITY

The present disclosure finds applications in, for example, non-volatile memory devices incorporated in various semiconductor devices.

### REFERENCE SIGNS LIST

1 non-volatile memory device
2 differential amplifier
3 driving transistor
4-8 current mirror
9 switch
10, 11 inverter
15 storage circuit
21, 22 input transistor
23, 24 PMOS transistor
25 resistive element
41 input-side transistor
42, 51, 61 output-side transistor
71 input-side transistor
72 output-side transistor
73 resistive element
81 reference element
82 data element
100 non-volatile memory device
105 storage circuit
IV1-IV4 inverter
Md1 first data element
Md2 second data element
Mr1 first reference element
Mr2 second reference element
PM1, PM2 PMOS transistor
R1, R2 resistive element
Rr1 first reference resistor
Rr2 second reference resistor
S1, S2 switch
S3, S4 switch
SA sense amplifier

1. A non-volatile memory device comprising:
a first current mirror having:
a reference element configured as a memory element for which a program operation can be performed, and
a data element configured as the memory element, the data element being a target of the program operation;
a reference current generator connected to the data element and configured to be operable to generate a reference current; and
a storage circuit having the data element and the reference current generator,
wherein
the storage circuit is operable to read data based on a magnitude relationship between a current flowing through the data element and the reference current.

2. The non-volatile memory device according to claim 1, further comprising:
a second current mirror having a first input-side transistor and a first output-side transistor,
wherein
the reference current generator is the first output-side transistor.

3. The non-volatile memory device according to claim 1, wherein
the first current mirror has a voltage adder that adds a voltage to a gate-source voltage of the reference element.

4. The non-volatile memory device according to claim 3, wherein
the voltage adder is a first resistor connected to the source of the reference element.

5. The non-volatile memory device according to claim 1, further comprising:
a driving transistor;
a second resistor connected to the driving transistor;
a differential amplifier that drives the driving transistor based on a difference between the reference voltage and a sense voltage appearing at a first node at which the driving transistor and the second resistor are connected together; and
a third current mirror having a second input-side transistor connected to the driving transistor and a second output-side transistor connected to the reference element.

6. The non-volatile memory device according to claim 1,
wherein
a size of the data element is larger than a size of the reference element.

7. The non-volatile memory device according to claim 1,
wherein
the storage circuit has a switch connected between an application terminal for a supply voltage and a second node at which the reference current generator and the data element are connected together.

8. The non-volatile memory device according to claim 1, further comprising:
a fourth current mirror having a third input-side transistor, a third output-side transistor connected to the drain of the data element, and a third resistor connected to the third input-side transistor.
